(19) United States
(12) Patent Application Publication
(10) Pub. No.: US 2025/0113508 A1
(43) Pub. Date: Apr. 3, 2025

(54) WAFER-LEVEL CHIP SCALE PACKAGE TRANSIENT VOLTAGE SUPPRESSION DIODE DEVICE

(71) Applicant: Texas Instruments Incorporated, Dallas, TX (US)

(72) Inventor: THOMAS KRONENBERG, Dallas, TX (US)

(21) Appl. No.: 18/478,912

(22) Filed: Sep. 29, 2023

(51) Int. Cl. H01L 29/866; H01L 21/784; H01L 23/00; H01L 27/08; H01L 29/06

(52) U.S. Cl. CPC H10D 8/25; H01L 24/05; H01L 24/11; H01L 24/13; H01L 24/94; H10D 84/221; H10D 89/013; H01L 2224/05567; H01L 2224/1146; H01L 2224/13006; H01L 2224/13139; H01L 2224/13144; H01L 2224/13147; H01L 2224/13155; H01L 2224/13164; H01L 2224/94; H01L 2924/12035; H10D 62/115

(57) ABSTRACT

An example arrangement includes a semiconductor device having at least two vertical diode devices spaced from one another by isolation trenches. Each of the vertical diode devices includes: a first diffusion region of a first P-type or N-type conductivity formed in a device side surface of the semiconductor die, the first diffusion region extending into a first epitaxial layer of a second P-type or N-type conductivity opposite the first conductivity type; the first epitaxial layer formed over a semiconductor substrate of the first P-type or N-type conductivity. The semiconductor substrate includes a backside surface facing away from the device side surface of the semiconductor die; metal contacts on the device side surface of the semiconductor die are electrically coupled to the first diffusion region; and stud bumps formed on the metal contacts and arranged to form terminals of the semiconductor device.

### TECHNICAL FIELD

This disclosure relates generally to semiconductor devices, and more particularly to semiconductor transient voltage suppression (TVS) devices.

### BACKGROUND

Circuits that protect from transient voltages can be described as transient voltage suppression (TVS) devices or circuits. Diodes can be used in electronic circuitry as protection for certain input, output and power signals. Because electrostatic discharge (ESD) and other transient voltage events can damage semiconductor devices that are coupled to input, output, input/output and power signals, systems and circuit boards are implemented with transient voltage suppression (TVS) devices coupled to these signals. When an ESD event occurs due to a static discharge, a very high voltage (positive, or negative with respect to a ground) can be applied to a signal trace. An example is when a human manually connects a cable to a socket on a board, for example when a human makes a universal serial bus (USB) connection by inserting a cable connector into a receptacle. The human body can discharge static electricity into the board at thousands of volts, for example, +1-15 kV. The electrostatic discharge event will be of short duration, for example tens of nanoseconds. However, if the high negative or positive transient voltage is allowed to develop at the signal trace, circuitry coupled to the signal trace, typically semiconductor devices, can be permanently damaged.

TVS devices can be coupled at the input, output, input/output or power terminals to prevent damage from a transient voltage event. In an example a reverse-biased Zener diode is used as a current protection and voltage clamping device. Once the voltage at the protected signal exceeds a breakdown voltage for the Zener diode, the Zener diode will enter a breakdown mode and conduct the current to ground, and clamping the voltage at the protected signal to a level that does not damage other semiconductor devices coupled to the signal. After the transient voltage event ends, the Zener diode is again reverse biased, does not conduct current and therefore does not affect the normal operations on the signal. The Zener diode is designed so as not to be damaged during the transient voltage event, and the circuitry coupled to the signal remains permanently protected.

In order to be an effective TVS diode device useful for high frequency signals, the TVS diodes need to have low capacitance. In some applications, the TVS diode devices are coupled to high frequency switching data signals, for example universal serial bus (USB) signals that operate at switching speeds in the 10-30 Gigahertz range. The TVS diode devices can be coupled to the traces carrying the data signals and necessarily form a capacitive load on these signals. If the TVS diode device capacitance is too large, system performance is reduced (the capacitance loads the signals). In the conventional approach for a TVS device, when the semiconductor dies with the diodes are mounted to a leadframe, and the devices are then coupled to each other using a bond wire or a ribbon bond, each of these semiconductor device package components contributes to, and increases, the device capacitance. The lead frame, bond wire, and wire bonding processes also increase costs.

TVS diode devices having low capacitance, and packaged TVS diode devices that are low in cost and arranged for low cost and time efficient board assembly, such as surface mount technology, are needed.

### SUMMARY

In a described example, a method includes: forming vertical diode devices coupled to one another in semiconductor dies on a semiconductor substrate, the semiconductor dies having a device side surface and having an opposing backside surface; performing a wafer bumping process to form stud bumps on metal contacts coupled to the vertical diode devices on the device side surface of the semiconductor substrate; and performing wafer dicing to singulate individual semiconductor dies from the semiconductor substrate, the individual semiconductor dies including at least two vertical diode devices coupled to one another by the semiconductor substrate including the semiconductor dies, with the stud bumps forming terminals for the semiconductor dies.

In a further method example, the above method further includes: prior to performing the wafer dicing, forming a backside metal on the backside surface of the semiconductor substrate, the backside metal and the semiconductor substrate coupling the vertical diode devices together. In an additional example method, the above method further includes forming a backside coating over the backside metal that is of epoxy resin mold compound, epoxy, resin or plastic.

In another example arrangement, a semiconductor device includes at least two vertical diode devices spaced from one another by isolation trenches. Each of the vertical diode devices includes: a first diffusion region of a first P-type or N-type conductivity formed in a device side surface of the semiconductor die, the first diffusion region extending into a first epitaxial layer of a second P-type or N-type conductivity opposite the first conductivity type; the first epitaxial layer formed over a semiconductor substrate of the first P-type or N-type conductivity. The semiconductor substrate includes a backside surface facing away from the device side surface of the semiconductor die; metal contacts on the device side surface of the semiconductor die electrically coupled to the first diffusion region; and stud bumps formed on the metal contacts and arranged to form terminals of the semiconductor device.

In an additional example arrangement, a transient voltage suppression (TVS) diode device includes: a pair of diode devices coupled together. Each diode device includes: a P-type diffusion well formed at the device side surface of a semiconductor die, the well extending into an N-type epitaxial layer; a P+ type semiconductor substrate, the N-type epitaxial layer formed over a device side surface of the semiconductor substrate; isolation trenches extending from the device side surface of the semiconductor die through the P-type diffusion wells, through the N-epitaxial layer, and into the P+ semiconductor substrate, wherein the isolation trenches separate the pair of diode devices one from another; metal contacts formed on and electrically contacting the device side surface of the P-type diffusion wells; and stud bumps formed on the metal contacts to form a terminal coupled to each of the diode devices.

### BRIEF DESCRIPTION OF THE DRAWINGS

FIGS. 1A-1B illustrate, in projection views, a semiconductor wafer with individual semiconductor dies arranged in rows and columns on a device side surface, and an individual semiconductor die from the semiconductor wafer, respectively.

FIG. 2 illustrates, in a board side plan view, an outline of a semiconductor device of the arrangements.

FIG. 3 illustrates, in a circuit block diagram, an example application for a TVS diode device of the arrangements.

FIG. 4A illustrates an example semiconductor die of an arrangement, and FIG. 4B illustrates the same cross-sectional view with an example transient event current flow added. FIG. 4C illustrates, in a cross-sectional view, an alternative arrangement for a TVS diode of an arrangement. FIG. 4D illustrates, in a cross-sectional view, details of a semiconductor die of an additional arrangement.

FIG. 4E illustrates, in another cross-sectional view, details of an alternative example diode that can be used in a TVS diode device of an arrangement.

FIGS. 5A-5B illustrate, in additional cross-sectional views, an alternative arrangement for a TVS diode device in FIG. 5A; and in FIG. 5B example current flow for the alternative arrangement.

FIGS. 6A-6G illustrate, in a series of cross-sectional views, selected steps for a WCSP process for forming semiconductor devices of the arrangements.

FIG. 7 illustrates, in a flow diagram, selected steps of a method for forming the arrangements.

### DETAILED DESCRIPTION

Corresponding numerals and symbols in the different figures generally refer to corresponding parts, unless otherwise indicated. The figures are not necessarily drawn to scale.

Elements are described herein as “coupled.” The term “coupled” includes elements that are directly connected and elements that are indirectly connected, and elements that are electrically connected even with intervening elements or wires are coupled.

The term “semiconductor device” is used herein. A semiconductor device can be a discrete semiconductor device such as a bipolar transistor, a few discrete devices such as a pair of power FET switches fabricated together on a single semiconductor die, or a semiconductor device can be an integrated circuit with multiple semiconductor devices such as the multiple capacitors in an A/D converter. The semiconductor device can include passive devices such as resistors, inductors, filters, sensors, diodes or active devices such as transistors. The semiconductor device can be an integrated circuit with hundreds or thousands of transistors coupled to form a functional circuit, for example a microprocessor or memory device. The semiconductor device can be a radio transceiver or a radar transceiver. The semiconductor device can be a receiver or a transmitter. When semiconductor devices are fabricated on a semiconductor wafer and then individually separated from the semiconductor wafer, the individual units are referred to as “semiconductor dies.” A semiconductor die is also a semiconductor device. In example arrangements, a semiconductor die carries at least two diode devices each having a terminal, the diode devices are coupled together to form a TVS diode device in the semiconductor die.

The term “semiconductor device package” is used herein. A semiconductor device package has at least one semiconductor die electrically coupled to terminals, and has a package body that protects and covers the semiconductor die. The semiconductor device package can include additional elements. For example, passive components such as capacitors, resistors, and inductors or coils can be included. In some arrangements, multiple semiconductor dies can be packaged together. In some approaches a semiconductor die is mounted to a package substrate that provides conductive leads, a portion of the conductive leads form the terminals for the packaged device. The semiconductor die can be mounted to the package substrate with a device side surface facing away from the substrate and a backside surface facing and mounted to a die pad of the package substrate. In wire bonded semiconductor device packages, bond wires couple conductive leads of a package substrate to bond pads on the semiconductor die. Alternatively, the semiconductor die can be mounted facing the package substrate using conductive post connects in a flip chip package. The semiconductor device package can have a package body formed by a thermoset epoxy resin in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions provide the terminals for the microelectronic device package. In the arrangements, a backside coating can be formed over some example arrangements for a wafer-level chip scale package (WCSP) device. In other example arrangements, no backside coating is formed, and the WCSP device is free from mold compound or other coatings.

The term “package substrate” is used herein. A package substrate is a substrate arranged to receive a semiconductor die and to support the semiconductor die in a completed semiconductor device package. Package substrates useful with the arrangements include conductive lead frames, molded interconnect substrates (MIS), partially etched lead frames, pre-molded lead frames, and multilayer package substrates.

The term “scribe lane” is used herein. A scribe lane is a portion of semiconductor wafer between semiconductor dies. Sometimes in related literature the term “scribe street” is used. Once semiconductor processing is finished and the semiconductor devices are complete, the semiconductor devices are separated into individual semiconductor dies by severing the semiconductor wafer along the scribe lanes. The separated dies can then be removed and handled individually for further processing. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “WCSP” is used herein. The term WCSP, or “wafer-level chip scale package”, refers to a method of manufacturing semiconductor devices where the packaging processes are formed at the wafer level. In contrast to discrete packaging methods, where individual semiconductor dies are mounted to a substrate, connected to terminals by wire bonding or by solder balls or columns, and then molded in a protective mold compound, in WCSP methods, the die mount, package substrate, and wire bonding steps are eliminated. In the arrangements, WCSP processing is used to form the TVS diode devices without the need for a package substrate such as a leadframe, without electrical connections such as wire bonding, and without a molded package body, reducing costs and reducing the size of the devices, which further reduces the board area needed for mounting the TVS diode devices of the arrangements.

The terms “N-type” and “N+ type” are used herein to describe the conductivity types of diffusion regions, epitaxial layers, wells, and semiconductor substrates. An “N-type” or “N+ type” conductivity element has been doped with donor atoms to increase the carrier concentration of electrons. N-type conductivity includes N+ type. In an example, phosphorous or arsenic atoms are used. The terms “P-type” and “P+ type” are used herein to describe conductivity of diffusion regions, epitaxial layers, wells, and semiconductor substrates. A “P-type” or “P+ type” conductivity element has been doped with acceptor atoms to increase the carrier concentration of holes. In an example, boron atoms are used. P-type conductivity includes P+ type. In a diffusion region formed in a layer of material, ion implantation can be used to introduce donor atoms to control the conductivity, and thermal anneal processes can be used to diffuse the atoms to form the diffusion region. Wells and source/drain regions can be formed as diffusion regions at the surface of another layer. Buried conductivity regions can be formed by covering a diffusion region with another layer. In epitaxial layers, the donor atoms can be added during a gas phase epitaxial growth over a crystal substrate, such as a semiconductor substrate. A semiconductor substrate can be doped during manufacture by introducing impurity atoms into the crystal growth process. N+ type or P+ type conductivity regions have increased carrier concentrations when compared to N-type or P-type conductivity regions. A semiconductor wafer is a semiconductor substrate having a circular shape from a plan view of a device side surface, typically with a flat side for alignment purposes.

The term “vertical diode” is used herein. A “vertical diode” is at least one diode formed in a vertical N-P-N or a vertical P-N-P structure where the semiconductor substrate forms part of the diode. Other diodes may be formed in the structure as well. In example arrangements, N-type, N+ type, P-type or P+ type conductivity regions are used to form wells, source/drain diffusion regions, epitaxial layers, buried conductivity layers in or over semiconductor substrates to form vertical diodes. Diodes are formed when a P-type region forms a junction with an N-type region. The vertical diodes of the arrangements can be formed in a P-N-P structure, or in an N-P-N structure. In the example arrangements, the vertical diodes include Zener diodes. Zener diodes have a property so that when connected to be reverse-biased with respect to a terminal and a voltage at the terminal exceeds a diode reverse breakdown voltage, the Zener diode will conduct current and “clamp” the terminal to a voltage determined by the current flowing through the Zener diode, which has a low resistance. Once the voltage applied to the terminal falls, the voltage applied to the Zener diode falls below the reverse breakdown voltage, and the Zener diode will stop conducting the current.

The term “ultra-low” capacitance is used herein to describe the capacitance of vertical diodes of the arrangements. As used herein, a diode has “ultra-low” capacitance when it can support data signals of at least 10 Gbps switching frequency, and up to 30 Gbps. The capacitance of diodes in the example arrangements can be about 0.2 picofarads, or less.

To form a TVS diode device in a conventional approach, a pair of semiconductor dies, each having a Zener diode, are mounted to a lead frame, with electrical contact between the device side terminals of the dies and terminals of the lead frame. A bond wire or bond ribbon couples backside contacts of the dies, which are spaced from one another. A signal terminal and a ground terminal are formed on the leadframe portions contacting the device side of the dies, each contacting one of the two Zener diodes. In this way, two TVS diodes are back-to-back coupled so that a current that flows from a positive transient voltage or from a negative transient voltage at the protected trace is coupled to ground. For either case (positive or negative transient voltage), one of the pair of Zener diodes will see a reverse breakdown voltage and act as a voltage clamp on the signal line, protecting other devices coupled to the signal line from the transient voltage.

In the example arrangements, vertical diode devices include Zener diodes formed between a P+ type substrate (or, alternatively an N+ type substrate) and an N-type or N+ type epitaxial layer, (or alternatively a P-type or P+ type epitaxial layer.) The Zener diodes are arranged to be reverse biased with respect to a terminal or signal trace. Additional diodes can be formed in parallel and in series with the Zener diodes to provide bi-directional current flow and increase performance.

In an example arrangement, vertical diodes are formed in a vertical structure, with a doped well or doped diffusion region formed in an epitaxial layer that is formed over a semiconductor substrate. The well or diffusion region is formed on a device side surface of the semiconductor device and is doped to a first conductivity type, for example a P-type well can be used. (Alternatively, an N-type well can be used.) The epitaxial layer is formed of semiconductor material doped to an opposite conductivity type, for example, a N-type epitaxial layer (or, in the alternative structure, a P-type epitaxial layer.) The epitaxial layer is formed on a semiconductor substrate doped to the same conductivity type as the well or diffusion region, for example a P-type doping such as P+ type doping. (In the alternative structure, an N-type or N+ type doping can be used). By contacting the device side surface of the vertical structure in the well, and by contacting the backside surface of the semiconductor substrate, a diode is formed with a vertical P-N-P structure in the first example, and with a vertical N-P-N structure in the alternative structure. Additional doped regions such as buried layers, or additional source/drain diffusion regions, can be used in alternative arrangements to increase performance of the diodes. Additional diodes can be formed.

In certain example arrangements described herein, vertical diodes are formed using the P-N-P structure. In an example arrangement, a pair of vertical diodes that are series coupled by the semiconductor substrate are formed to provide a TVS diode device. Each of the vertical TVS diode devices has a P-N-P structure. In the alternative structure, a pair of vertical diodes is formed on a semiconductor die, each vertical diode with an N-P-N vertical structure. To increase performance and control the breakdown voltages, additional elements such as a second epitaxial layer, buried layers, and the use of both N-type and P-type doped regions can be used in addition to the vertical P-N-P structure or to the vertical N-P-N structure. Ultra-low capacitance TVS diode devices are achieved by use of the arrangements.

When a voltage is applied to a terminal of the vertical diode devices with a P-N-P structure, a P-N junction of a first diode is forward biased but a cathode of a second diode coupled to the first diode is reversed biased with respect to the voltage, in this example the second diode is a reverse-biased Zener diode. When a voltage that is sufficiently high (equal to or greater than a Zener diode forward breakdown voltage (V_{brf}) is at the terminal, the Zener diode enters a breakdown mode and the vertical diodes conduct current. When the vertical diodes are coupled between a terminal and ground, the current from the transient voltage event is discharged from the terminal into the ground, preventing damage to other devices coupled to the terminal. Once the transient voltage at the terminal falls, the Zener diode is again reverse-biased and not conducting, so the vertical diodes stop conducting, providing protection to other devices coupled to the terminal without affecting normal operations. The vertical diodes are not damaged during the transient event and so the other devices coupled to the signal remain protected for future transient voltage events. By using two vertical diodes including Zener diodes coupled back-to-back between the signal and ground, so that one is reverse biased with respect to the signal terminal, and the other is reverse biased with respect to the ground terminal, the TVS diode devices of the arrangements protect from both negative (less than ground) and positive voltage transient events.

Advantageously, the novel vertical diodes of example arrangements are formed using WCSP. In the methods for the arrangements, a package substrate such as a lead frame, die mounting, wire bonding, and molding are not needed, significantly reducing costs and further reducing the device capacitance.

In an example WCSP fabrication method, pairs of vertical diodes are formed in semiconductor dies, each die having a vertical component structure with wells or source/drain regions formed in an epitaxial layer that is formed over a semiconductor substrate. The vertical diodes are spaced from one another and isolated from one another by isolation trenches extending through the wells and the epitaxial layers and into, but not through, the semiconductor substrate. The vertical diodes are electrically coupled by the semiconductor substrate. Wafer stud bumping is performed on the device side surface, in an example arrangement each die has two vertical diodes with one stud terminal for each of the vertical diodes. A stud bump forms a terminal (in an example, two stud bumps, one for each of two vertical diode devices, which are coupled back-to-back through the semiconductor substrate) of each of the diodes of the device pair. In an example WCSP process, the stud bumps on the device side of the semiconductor wafer are then covered with a support tape or film. In one approach, the wafer is then thinned using a wafer backgrinding process on the backside surface, and a backside metallization is performed to provide backside metal over the wafer. Use of the backside metal lowers the resistance of the diode devices, and increases performance. Each semiconductor die in this approach has a backside surface contact to metal that couples the two diodes together at the backside of the semiconductor substrate, forming a low resistance connection between the two diodes. A protective backside coating can be formed over the backside metal, and the completed wafer is then singulated using a dicing saw to separate the individual dies one from another. In the alternative arrangements including the backside metal coating, each of the WCSP semiconductor dies has a pair of diodes electrically coupled at the backside metal coating in a back-to-back TVS circuit, with two terminals at the device side, one terminal coupled to one of the diodes, the other terminal coupled to the other one of the back-to-back diodes.

In an alternative WCSP method, the semiconductor substrate is not thinned in a backside process, but instead is kept to a predetermined thickness (greater than the thickness of the semiconductor wafer in the example described in the preceding paragraph.) The thick semiconductor wafer is singulated to form dies (in this approach, singulation is performed without any backside process, by not depositing the backside metal and without the protective backside coating of the example in the preceding paragraph). In this alternative approach, the vertical diodes of a back-to-back vertical diode pair in a semiconductor die are coupled through the doped semiconductor substrate itself. Current flows in the semiconductor substrate beneath the isolation trenches to electrically couple the two diodes when one of the two diodes enters breakdown mode and conducts, for a positive or a negative voltage at the signal terminal that exceeds the breakdown voltage. During a transient ESD event, the vertical diodes will carry current to the ground terminal.

Either of the two method arrangements results in TVS diode devices that have stud bump terminals arranged for mounting using surface mount technology (SMT), one terminal can be coupled to a power or signal trace, and the other to a ground trace. The WCSP TVS diodes of the arrangements have ultra-low capacitance (which is enhanced further by eliminating the lead frame, the die attach material, and the bond wire or ribbon bond that are used to couple the individual dies in a conventional semiconductor device package.) Use of the vertical P-N-P (or alternatively, use of a vertical N-P-N) structure with the backside of the semiconductor substrate forming part of the circuit allows the two TVS diodes to be coupled through either a backside metal coating, or alternatively through the semiconductor substrate itself below the isolation trenches, eliminating the need for additional terminal connections (which would be needed in a planar semiconductor structure, for example in a conventional planar metal-oxide-semiconductor (MOS) process.) The completed TVS diode devices of the arrangements can have smaller area than devices formed in conventional semiconductor device packages, saving board area. The TVS diode devices of the arrangements have ultra-low capacitance, enabling use of the TVS diode devices at high frequencies without degrading signal performance.

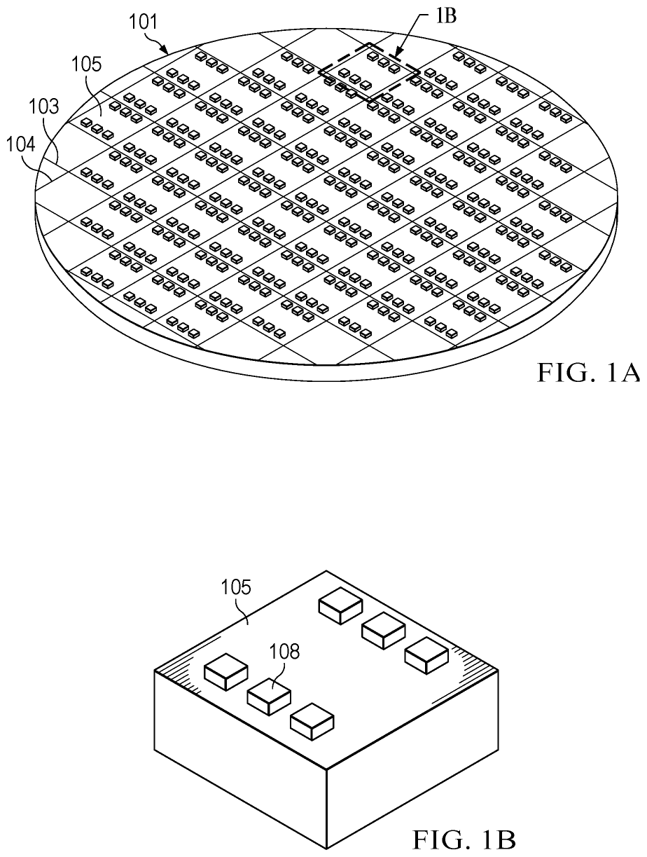

FIGS. 1A and 1B illustrate, in two projection views, a semiconductor wafer 101 having semiconductor dies 105 formed on it, and an individual semiconductor die 105, respectively. In FIG. 1A, a semiconductor wafer 101 is shown with an array of semiconductor dies 105 formed in rows and columns on a device side surface. The semiconductor dies 105 can be formed using processes in a semiconductor manufacturing facility, including ion implantation, doping, anneals, oxidation, dielectric and metal deposition, photolithography, pattern, etch, chemical mechanical polishing (CMP), electroplating, epitaxial deposition, and other processes for making semiconductor devices. Scribe lanes 103 and 104, which are perpendicular to one another and which run in parallel groups across the wafer 101, separate the rows and columns of the completed semiconductor dies 105, and provide areas for dicing the wafer 101 to separate the semiconductor dies 105 from one another.

FIG. 1B illustrates a single semiconductor die 105 taken from semiconductor wafer 101. Semiconductor die 105 includes bond pads 108, which are conductive pads that are electrically coupled to devices (not shown) formed in the semiconductor die 105. Not shown for clarity of illustration are under bump metallization (UBM) portions which can be formed over the bond pads to improve plating and adhesion. Materials used in UBM include nickel, gold, palladium, titanium, tungsten and copper seed layers, and these can be used to enable plating, reduce tarnish and corrosion and to retard diffusion of metals. In example arrangements, as further described below, each semiconductor die will have two bond pads or metal contacts on the device side surface, and stud bumps can be formed on the bond pads in a wafer scale bumping operation. Note that while the example semiconductor die 105 is shown with six bond pads 108 for illustration purposes, the TVS diode devices of example arrangements may have only two terminals, and thus two bond pads or metal contacts are formed on a semiconductor die, one of the terminals is coupled to a first vertical diode, and the other one of the terminals is coupled to a second vertical diode. The two vertical TVS diodes are electrically coupled together by the semiconductor substrate of the semiconductor die. Note as used in this description, a “TVS diode” includes at least one Zener diode that acts to protect a trace or signal it is coupled to. However, additional diodes are formed in the devices, including additional Zener diodes, and additional P-N junction diodes, to ensure the devices can conduct current bidirectionally to efficiently couple Zener diodes to the bond pads for both positive and negative transient voltage events. Several diodes can be formed in a semiconductor die that includes a “TVS diode.” Note that because in the arrangements, no wire bonding is performed, the term “metal contact” is used for metal over a diffusion region that provides an electrical connection to the diffusion region, instead of the term “bond pad.” In the arrangements, stud bumps are formed on the metal contacts.

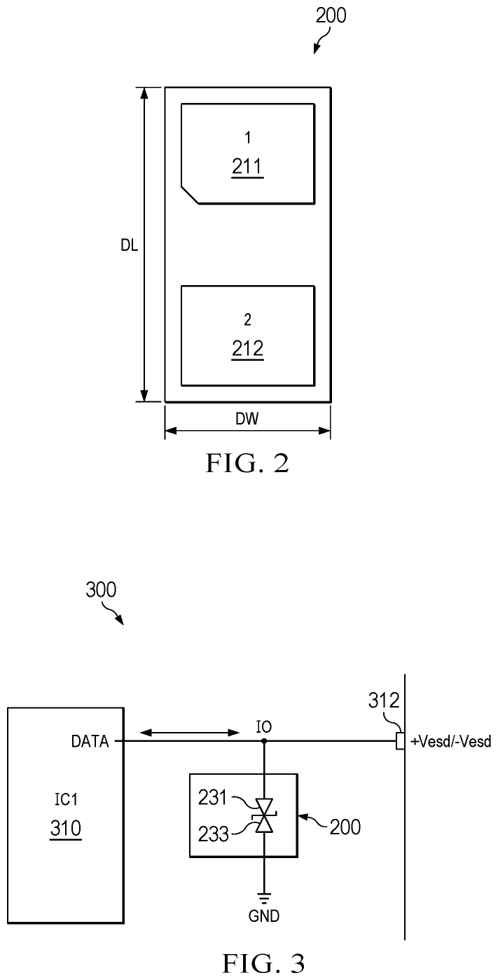

FIG. 2 illustrates, in a board side plan view, an outline for a TVS diode device 200 of an example arrangement. The TVS diode device 200 has two terminals 211, 212, and the two terminals (labeled “1” (211) and “2” (212) in FIG. 2) can be stud bumps arranged for mounting to a board or module using surface mount technology (SMT). The two terminals 211, 212 can be copper or copper alloys, for example, formed in a wafer bumping process, and the exposed surface of the stud bumps 211, 212 can be further plated with additional metals to make the terminals more solderable and to reduce corrosion and oxidation. For example, plating of nickel, palladium, gold, titanium, tin, tungsten, silver and combinations or alloys of these can be used. A nickel-palladium or nickel-gold plating can be used. In an example process, the TVS diode device 200 can have a length labeled “DL” of about 460 microns, and a width labeled “DW” of about 210 microns, and the stud bumps 211, 212 can have a width of about 140 microns, to provide a footprint similar to, but smaller than, the standard “0402” packaged component for SMT mounting (which has a length of about 1 millimeter, and a width of about 0.5 millimeters and SMT terminals of about 200 by 100 microns). The WCSP TVS diode devices of the arrangements can also be made smaller and thinner than a similar standard “0402” packaged device, in one example an arrangement has a 0.46 mm×0.21 mm footprint and a thickness of about 0.175-0.25 millimeters, less than the packages formed without use of the arrangements.

FIG. 3 illustrates, in a circuit block diagram 300, an example application for a TVS diode device 200 of the arrangements. In FIG. 3, the TVS diode device 200 is shown with two Zener diodes 231, 233 coupled back-to-back so that the cathodes of the two terminals are facing one another and coupled together. In the example application of FIG. 3, the TVS diode device 200 is coupled between an IO signal (the IO signal is shown coupled between a terminal 312 and to the integrated circuit 310, a signal trace on a system board, for example) and ground (labeled “GND” in FIG. 3). Because for a positive or negative voltage transient on the signal I/O, one of the two Zener diodes 231, 233 in TVS diode device 200 is reverse biased (cathode is facing the positive voltage), no current will flow for normal operations on the signal I/O.

In an example where a high positive voltage transient such as a voltage “+Vesd” appears on the IO signal at terminal 312, the Zener diode 233 of the TVS diode device 200 will enter breakdown mode and conduct current to ground. In another example where high negative voltage such as a transient voltage “−Vesd” appears on the IO signal, the Zener diode 231 will enter breakdown mode and conduct the negative current to ground. In either example the TVS diode device 200 has a “hold” or “clamp” voltage during the voltage transient event that is still low enough to prevent damage to semiconductor devices (such as IC1, 310 in FIG. 3, coupled to transmit or receive data on the IO signal.) In an example case, the data on the I/O signal may normally be at voltages of about +3 Volts or about zero Volts, the voltages corresponding to a ‘1’ or a ‘0’ value data bit on the IO signal. The hold voltage for the TVS diode device 200 may be around +/−10 Volts or less. By use of the TVS diode device 200 on the IO signal, semiconductor devices such as 310 coupled to the data signal will not be damaged by an ESD voltage transient, because the voltage at terminal 312 (and on the IO signal) will be held to the TVS diode hold voltage during the ESD transient event. The breakdown voltage of the TVS diode device 200 will be higher than normal operating voltages of about +3 Volts on the IO signal, so that during normal operations the TVS diode device 200 does not affect the data on the IO signal.

Further, the ultra-low capacitance of the example TVS diodes formed using WCSP methods of the arrangements reduces the noise and capacitive load on the IO signal (when compared to TVS diodes of prior approaches formed without use of the arrangements), so that in an example device made using the arrangements, data rates of 20 Gbps-30 Gbps, or higher, can be supported. In an example arrangement formed in an example semiconductor process, the capacitance of example arrangements has been shown to be about 0.2 picofarads, or less.

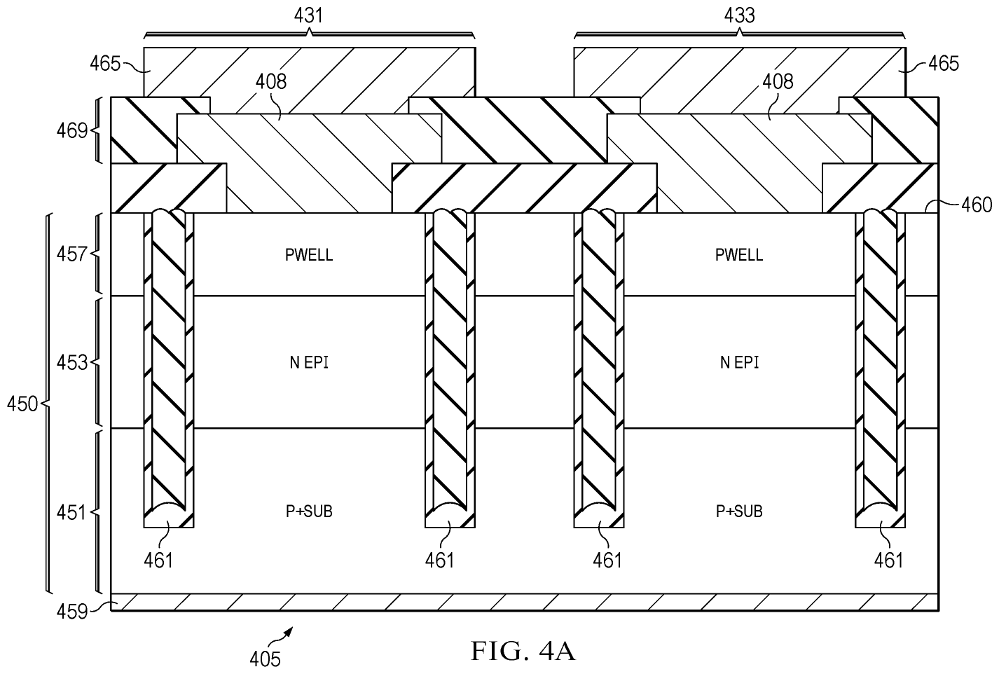

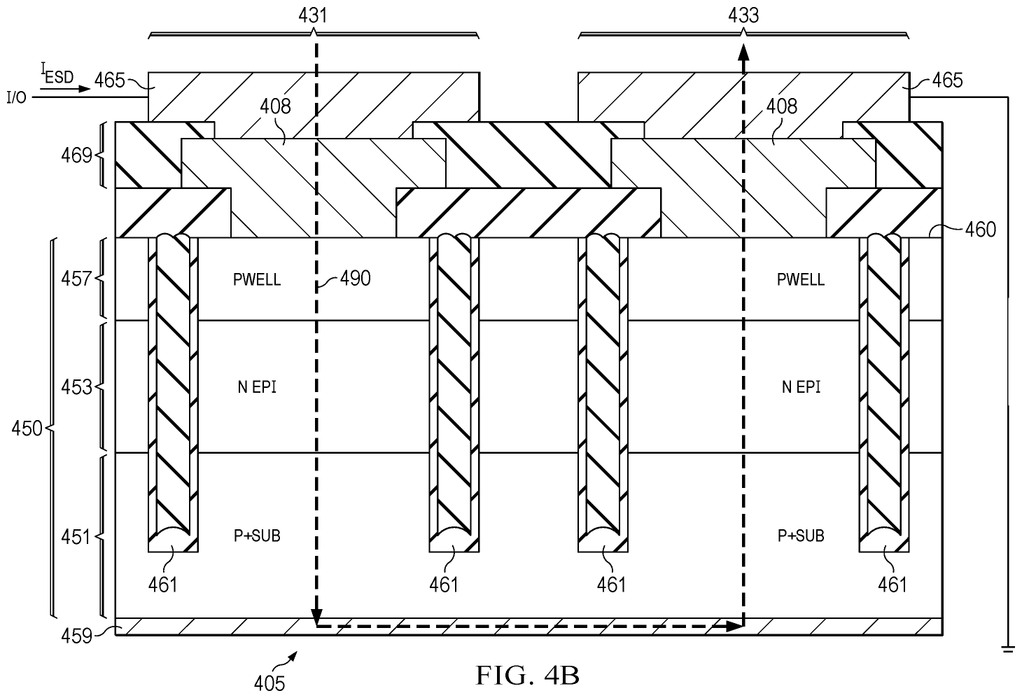

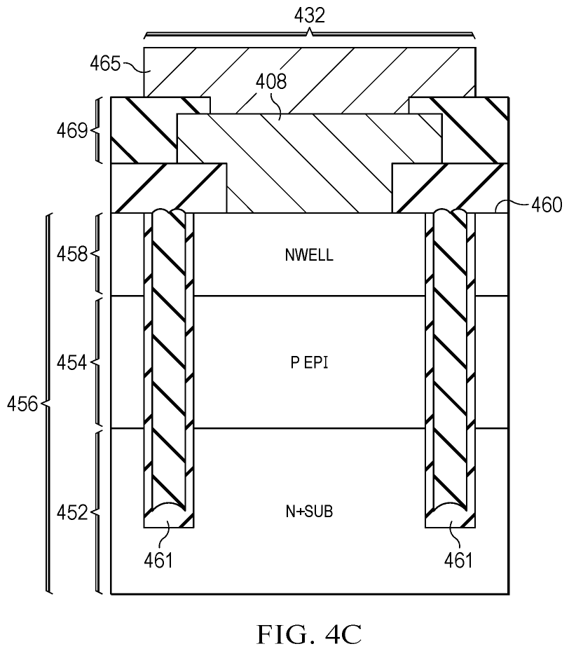

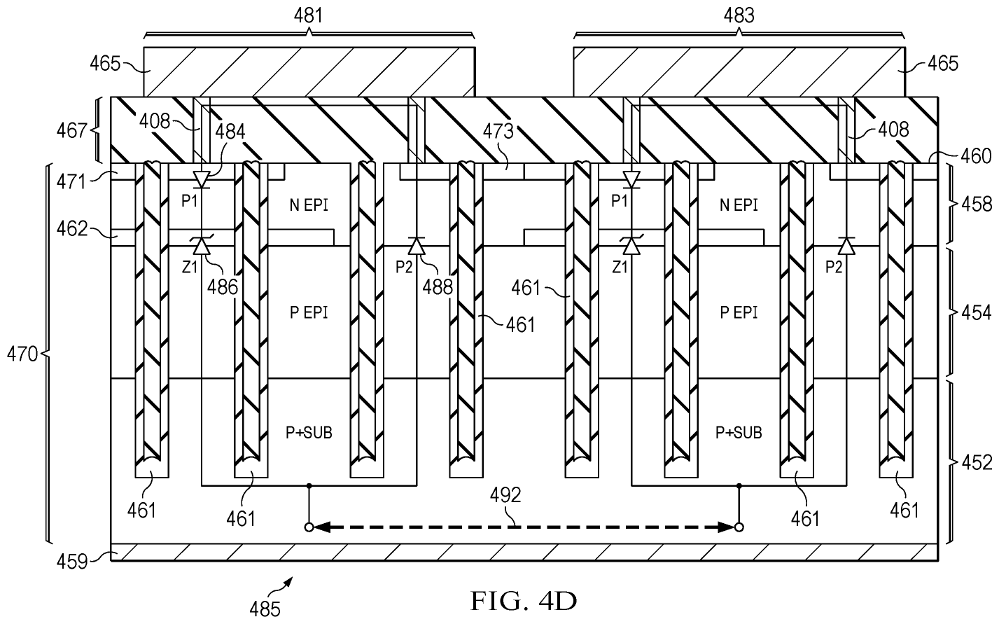

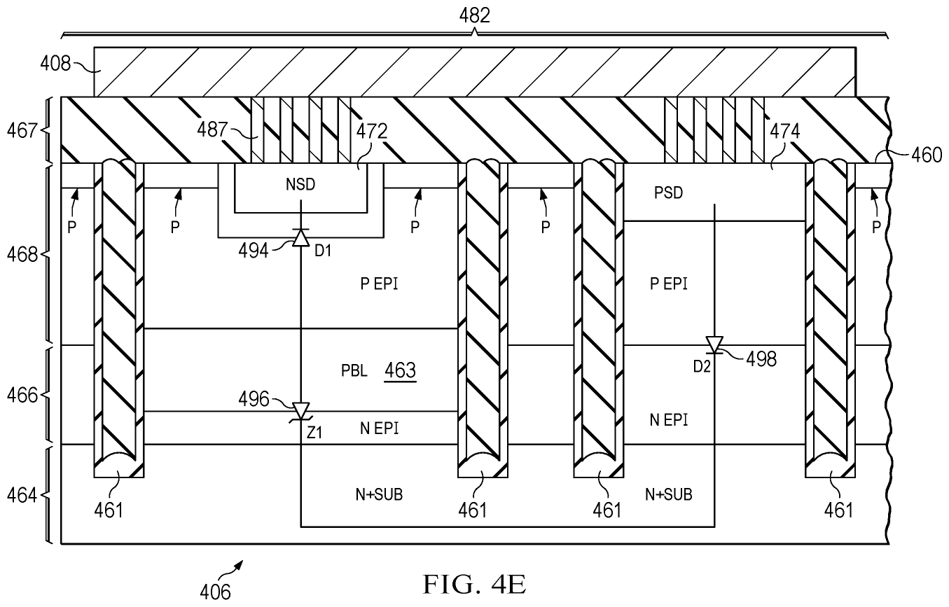

FIG. 4A illustrates, in a cross-sectional view, an example semiconductor die 405 of an arrangement, and FIG. 4B illustrates the same cross-sectional view with current flow added in an example transient event. In FIG. 4A, semiconductor die 405 includes two vertical TVS diodes 431 and 433, (similar to the diodes 231, 233 of FIG. 3), that are isolated from one another by isolation trenches 461, which are filled with insulating material. In the example arrangement of FIG. 4A, a P-N-P vertical structure 450 is formed. The P-N-P vertical structure 450 includes semiconductor substrate 451 that has a P+ type doping, for example formed by use of phosphorous as a dopant. An epitaxial layer 453 has a N-type doping, for example it can be doped with boron during a gaseous epitaxial layer deposition. A P-type well 457 is formed extending into the epitaxial layer 453 at a device side surface 460, P-type well 457 can be doped using arsenic as an implanted ion, for example. A backside metal 459 is shown formed on a backside surface of the semiconductor substrate 451 that, along with the semiconductor substrate 451 below the isolation trenches 461, electrically couples the vertical diodes 431, 433 together. A metal contact structure 408 is shown formed on the device side surface 460 for each diode 431, 433 and contacting the P-well layer 457.

A stud bump layer 465 is shown formed over the metal contact layer 408. In an example method, the semiconductor wafer is completed to a point including the metal contacts 408 for each vertical diode 431, 433, and is covered with the protective overcoat (PO) layer 469. An additional polyimide layer can be formed around the metal contacts. The metal stud bumps 465 can be formed in a wafer bumping facility using electroplating of copper or copper alloy, gold or gold alloy, or similar metals that can be plated, by opening the protective overcoat layer 469 (a dielectric that protects the device side of the semiconductor wafer, for example a silicon nitride or silicon oxynitride can be used) to expose the metal contacts 408, and using a seed layer and plating processes, performing the wafer bump plating operation. The plated bumps can be patterned to form stud bumps 465 arranged for surface mount technology (SMT) by use of solder mounting to conductive traces on a board or module.

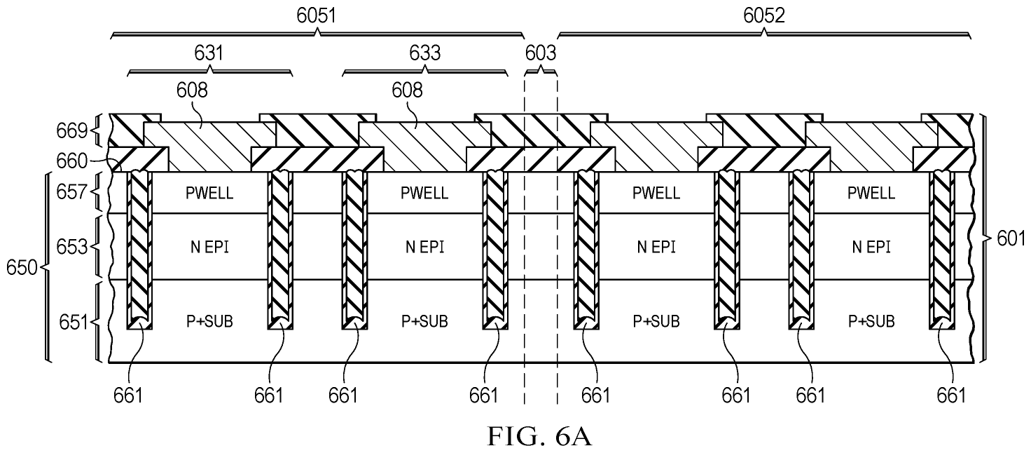

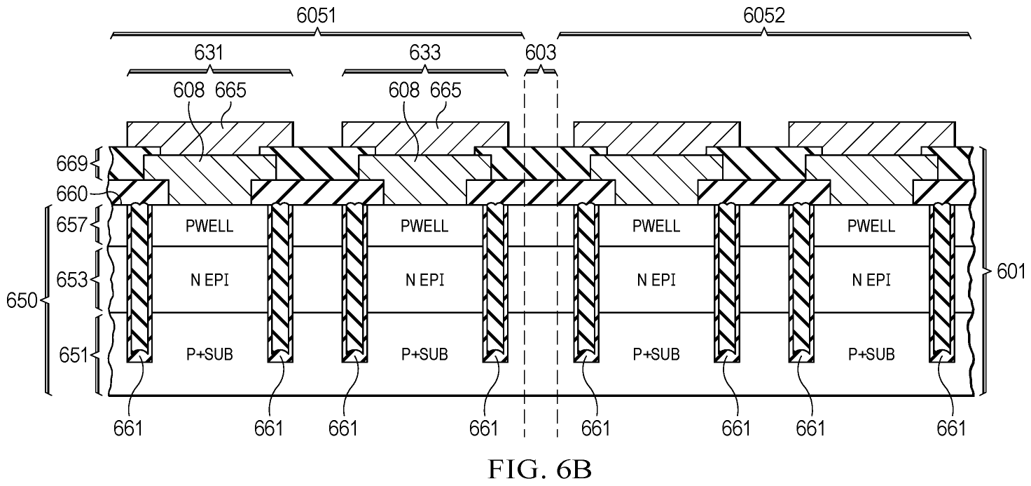

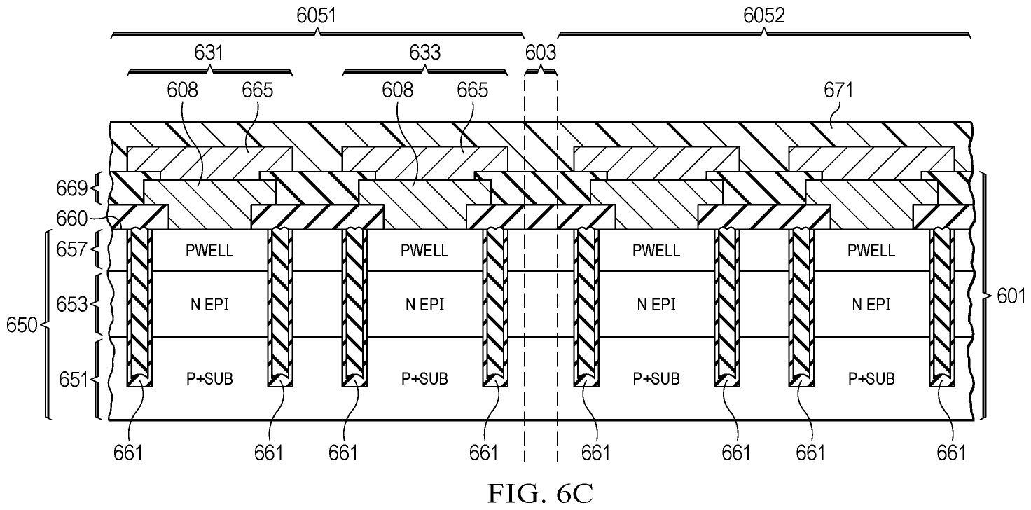

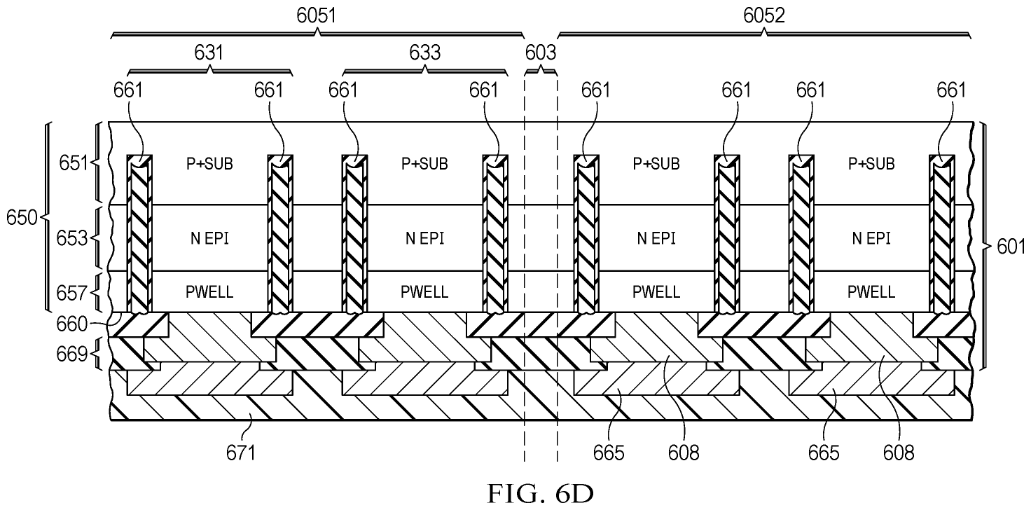

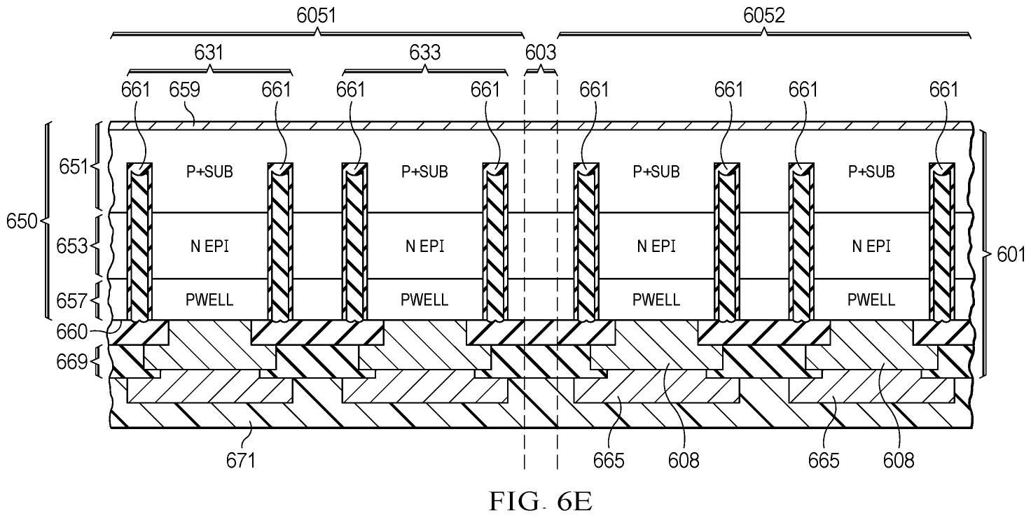

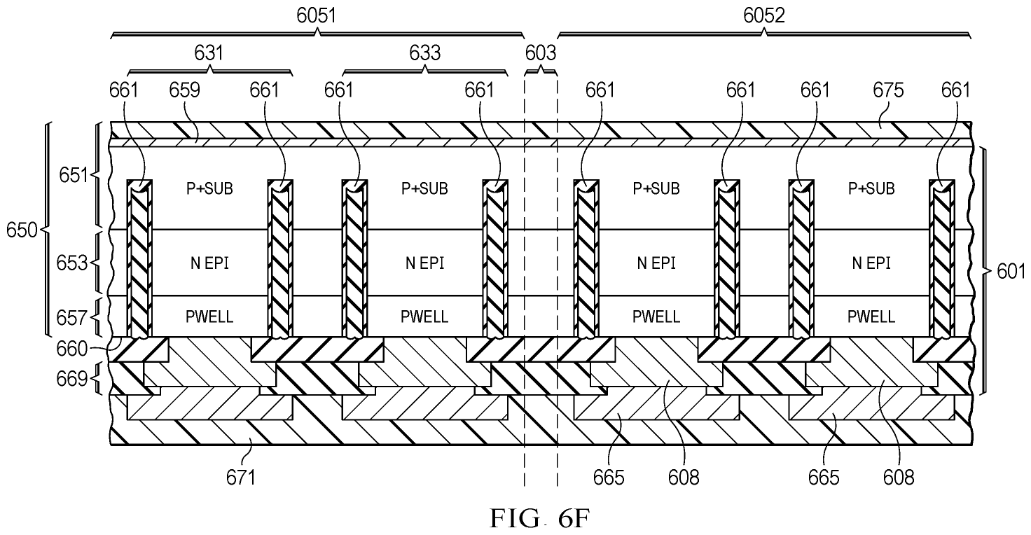

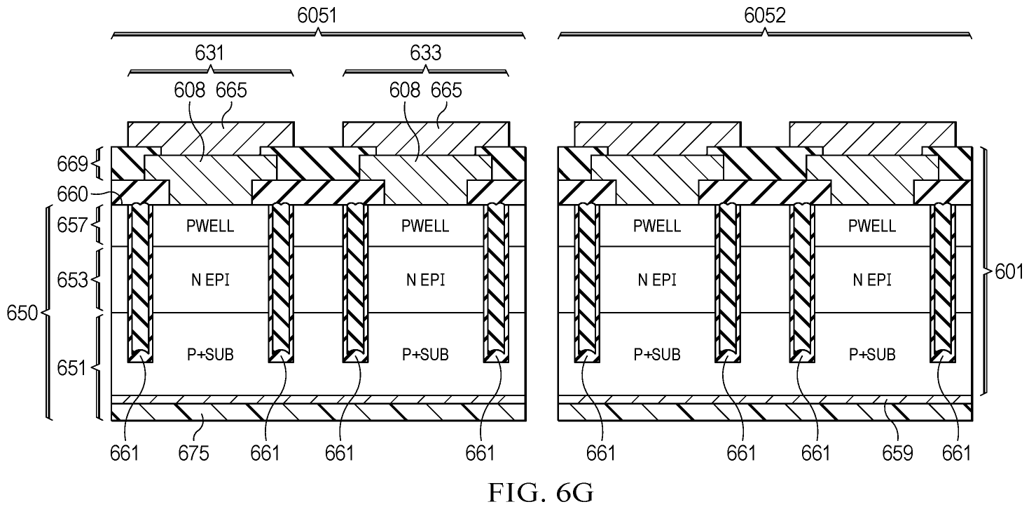

The isolation trenches 461 extend into the vertical P-N-P structure 450 from the device side surface 460. The trenches 461 electrically isolate the TVS diodes 431 and 433 one from another. In the example shown in FIG. 4A, a conductive backside metal layer 459 connects the two TVS diodes together, as shown in FIG. 3 the two TVS diodes (see FIG. 3, diodes 231, 233) are coupled together in a back-to-back configuration. The backside metal 459 can be formed by a PVD process in a backside process after the wafer processing is otherwise completed and after wafer bumping is performed. In addition, a backside coating (not shown in FIGS. 4A-4B for simplicity of illustration, see later 675 in FIG. 6G below), such as epoxy resin mold compound, can be deposited after the backside metallization, to protect the backside metal 459 from oxidation or corrosion.

FIG. 4B illustrates, in the same cross-sectional view, the semiconductor die 405 of FIG. 4A, now shown with an ESD current I_{ESD} flowing during an ESD transient voltage event, as shown the by dashed arrow line 490. When the voltage at the signal I/O exceeds a forward breakdown voltage V_{BRF}, such as for a positive voltage ESD event, the TVS diode structure in semiconductor die 405 is triggered and current I_{ESD} flows through the TVS diode 431 and through the TVS diode 433 to ground (labeled “GND”). The two TVS diodes 431 and 433 are series coupled, in this example, by the semiconductor substrate 451 and backside metal layer 459, which can be an aluminum metal layer formed on the backside of the semiconductor substrate. Other conductors can be used, such as copper. By varying the thickness and material of the backside metal 459 the resistivity of this connection can be kept low, so that the voltage across the TVS diode structure is also kept low, and a hold voltage will be established at levels that will not damage a semiconductor device coupled to the signal I/O. The reverse-biased diode 431 will turn on in breakdown mode when the positive voltage exceeding V_{BRF} is on the signal I/O, and will turn off again once the voltage falls below the breakdown voltage, clamping the voltage on signal I/O to a safe voltage during the transient voltage event. Diode 433 becomes reverse biased during a negative transient voltage event when the negative voltage exceeds a breakdown voltage −V_{B}RF, such as a negative ESD event, and will protect devices coupled to the signal I/O from the negative ESD voltage by holding the voltage to a safe (negative) voltage.

FIG. 4C illustrates, in another cross-sectional view, an alternative vertical structure for the diodes. In FIG. 4C, instead of a vertical P-N-P structure as in FIGS. 4A-4B, a vertical N-P-N structure 456 is used. An N+ doped substrate 452, such as a silicon semiconductor wafer, has a P-type epitaxial layer 454 formed over it. An N-type well 458 is formed at the device side surface 460 of the N-P-N structure. A terminal for connection to a TVS diode 432 is formed by the metal contact 408 in contact with the N-well 458, while the other terminal is the N+ substrate 452. The N-P-N structure of FIG. 4C may be preferred over the P-N-P structure of FIG. 4A, because the electron carriers in an N+ substrate (see substrate 452 in FIG. 4C) have higher mobility than the hole carriers of the P+ substrate (see 451 in FIG. 4A), potentially increasing device performance. Stud bump 465 is shown formed on metal contact 408 to complete the TVS diode 432. In a completed example arrangement, at least two of the vertical TVS diodes are formed in a semiconductor die, series coupled by the semiconductor substrate 452 and, in some arrangements, by a backside metal over the semiconductor substrate.

FIG. 4D illustrates, in a further cross-sectional view, details of another example arrangement including a pair of TVS diode devices formed in a semiconductor die to form a TVS diode device 485. As described above, in example arrangements P-type regions and N-type regions can be used, to form either a vertical P-N-P or a vertical N-P-N structure as part of a TVS diode device, in addition, in the arrangements the TVS diode devices can have additional doped regions so that the TVS diode devices are designed to be ultra-low capacitance, and as for the arrangements of FIGS. 4A-4C, are bi-directional. In FIG. 4D, the vertical structure 470 includes two epitaxial layers (458, 454), buried layers 462 that are additional doped regions, and both N-type and P-type source/drain regions 471, 473 for each of diode devices 481, 483 that form the TVS diode device 485.

In FIG. 4D, the doped regions can be used to form a vertical P-N-P (or alternatively, a vertical N-P-N) structure. For explanation, a vertical P-N-P structure is first described. In FIG. 4D, the vertical structure 470 includes a semiconductor substrate 452. The semiconductor substrate 452 can be doped to a P+ doping concentration in the illustrated P-N-P example. A first P-EPI epitaxial layer 454 of the same doping type (but of different concentration, or the same concentration) can be formed over the semiconductor substrate 452. An N-type buried layer 462 is formed on the epitaxial layer 454. An N-type epitaxial layer 458 is then formed over a portion of the N-type buried layer 462 and the epitaxial layer 454. A source/drain diffusion region 471 is formed in the N-type epitaxial layer 458, in this P-N-P example this can be a P+ or P-type doped region. A metal contact 408 is formed on the device side surface 460 of the source/drain diffusion region 471. In addition to the vertical P-N-P structure formed by the source/drain diffusion region 471, the epitaxial layer 458, and the substrate 452, with buried region 454, in FIG. 4D, another current path is formed in a second area of the diode device 481 next to the P-N-P structure, with an N-type source/drain diffusion region 473 formed in epitaxial layer 458, but separated from the vertical P-N-P structure 470 by isolation trenches 461. The N-type epitaxial region 458 is over the P-type epitaxial layer 454 and the P+ substrate 452. A current path is then formed from the P+ substrate to the N-type epitaxial layer 458 and the N+ source/drain diffusion region 473, where metal contact 408 couples the region 473 to the stud bump 465. As shown by the dashed line 492 in FIG. 4D, the current flow is bidirectional, for both positive and negative transient voltage events.

Each of the diode devices 481, 483 is replicated and form a TVS circuit coupled by the semiconductor substrate 452 and backside metal 459. In one example (see FIG. 3, TVS diode device 200 with diode devices 231, 233) by coupling the stud bump 465 for device 481 to a signal terminal, and by coupling the corresponding stud bump 465 for the device 483 to a ground terminal (or vice-versa), the TVS diode devices 481, 483 form a TVS device 485 that can be coupled to protect a signal terminal from ESD transient voltage events. Note that in FIG. 4D, the protective overcoat layer (see 469 in FIG. 4B for example) is omitted for simplicity. The dielectric layer 467 is over the trench isolation 461 and metal contacts 408 extend through dielectric layer 467.

In FIG. 4D, the P-N junctions that form individual diodes are labeled as “P1”, “Z1”, and “P2” for each of the TVS diode devices 481, 483. In the P-N-P example in device 481 the diode 484 (labeled “P1”) is formed by the P-type source/drain diffusion 471 and the N-type epitaxial layer 458. Diode 486 (labeled “Z1”), a Zener diode, is reverse-biased with respect to a positive voltage at the stud bump 465 of diode device 481, and is formed by the P-type epitaxial layer 454 and the N-type buried layer 462. Diode 488 (labeled “P2”) is formed by the P-type epitaxial layer 454 and the N-type buried layer 462 and N-EPI layer 458. The diode device 483 has similar individual diodes with labels P1, P2, and Z1 arranged in the same manner. In operation, the TVS diode devices 481, 483 are bidirectional, so that when a negative potential greater than a breakdown voltage of the Zener diodes Z1 is at stud bump 465 of diode device 481, current can flow from a ground terminal (now a positive voltage with respect to the negative transient voltage) coupled to the stud bump 465 of the adjacent diode device 483.

In an alternative arrangement, the vertical structure 470 of FIG. 4D can be formed using a vertical N-P-N structure by reversing the conductivity types of each of the doped regions, the epitaxial layers, the semiconductor substrate, and the buried regions. FIG. 4E illustrates in another cross-sectional view an example vertical TVS diode 482 in a portion of a semiconductor die 406, to show the use of an alternative vertical TVS diode arrangement with N-P-N layers. To form a TVS diode device of the arrangements, two of these vertical TVS diodes will be formed in semiconductor die 406. In FIG. 4E, the semiconductor substrate 464 is an N+ conductivity type (labeled “N+SUB”). An N-type epitaxial layer 466 (N EPI) is shown over the N+SUB substrate 464. A P-type buried layer 463 (“PBL”) is shown over a portion of the N-type epitaxial layer 466 (N EPI), and with the N-type epitaxial layer 466 forms a Zener diode 496 (labeled “Z1”). The Zener diode 496 (Z1) is reverse-biased with respect to the semiconductor substrate 464 and metal contact 408. A P-type epitaxial layer 468 is formed over the N-type epitaxial layer 466 and over the P-type buried layer 463. An N-type well surrounds an N-type source/drain diffusion 472 at the device side surface 460 of the P-epitaxial layer 468, this P-N junction forms a diode 494 (labeled “D1.”) In an adjacent portion of the TVS diode device 482, a P-type source/drain diffusion 474 (labeled “PSD”) at device side surface 460 is in contact with metal contact 408 through dielectric layer 467 using an array of tungsten plugs, as an example.

P-type epitaxial layer 468 is formed over the N-type epitaxial layer 466 and the P-N junction forms a diode 498 (labeled “D2”) that is forward biased when a positive voltage is at the contact 408 with respect to the voltage at the N+ substrate 464. The TVS diode device 482 is bidirectional, and current can flow when the metal contact 408 has a positive voltage or a negative voltage on it (with respect to the N+ substrate 464). Isolation trenches 461 extend into the diode 482 device from the device side surface, through the epitaxial layers and into the N+ substrate 464. Current can flow beneath the isolation trenches to carry current during a voltage transient, for example.

A backside metal (not shown) can be formed on the backside surface of the N+ substrate 464 to decrease resistance and thereby increase device performance (see, for example, backside metal 459 in FIG. 4D). As shown in FIGS. 4D-4E, arrangements can be formed using a P-N-P vertical structure (in FIG. 4D) or an N-P-N vertical structure (in FIG. 4E). However, mobility of carriers in N+ substrates is greater than the mobility of carriers in P+ substrates, and so, depending on the characteristics of semiconductor process used to form the devices, the N+ substrates and the N-P-N arrangements may be preferred.

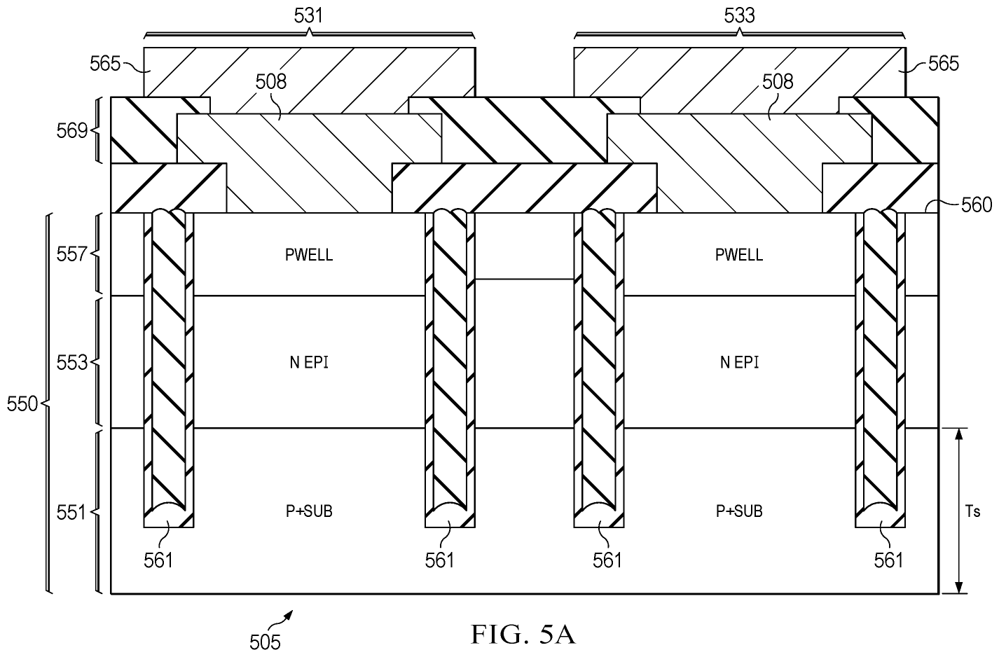

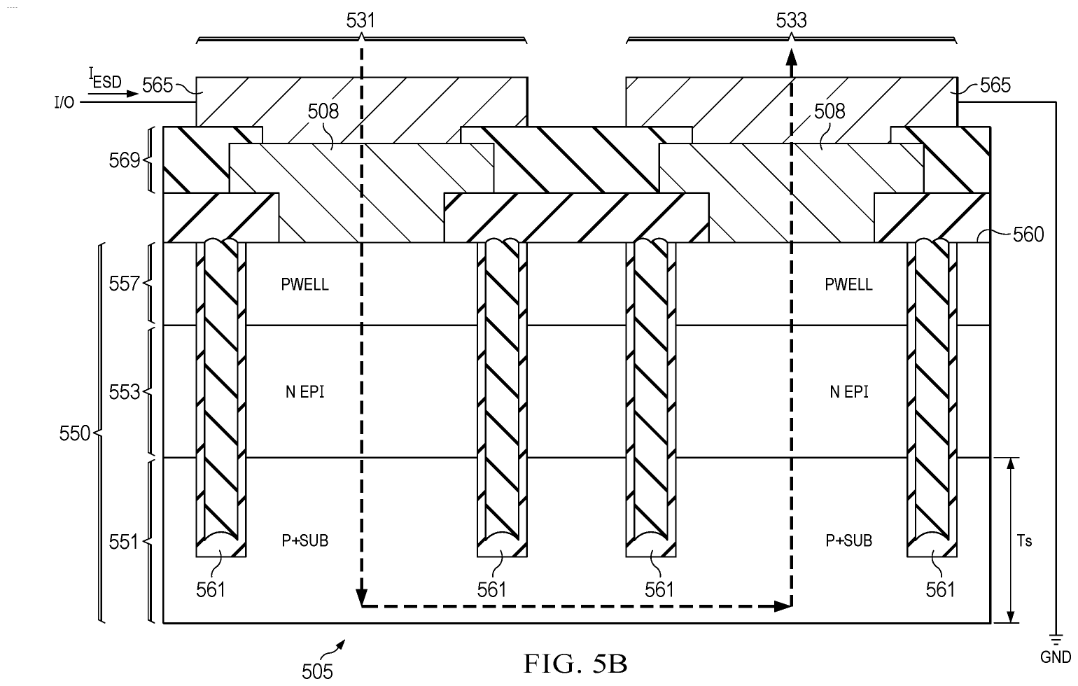

FIG. 5A illustrates, in another cross-sectional view, an alternative arrangement; and FIG. 5B illustrates an example current flow for the arrangement of FIG. 5A. In contrast to the arrangement of FIG. 4A, the arrangement in FIG. 5A does not have a backside metallization layer. In FIG. 5A, a semiconductor die 505 has diodes 531 and 533 formed in a vertical P-N-P structure 550. The semiconductor substrate 551 is of a material similar to the semiconductor substrate 451 of FIG. 4A but is of a greater thickness (labeled “Ts” in FIG. 5A) than the thinned semiconductor substrate 451. For the arrangements where no backside metal is used, a wafer thickness of about 7.5 mils (about 190 microns) is used.

The semiconductor substrate 551 in the illustrated example is doped to a P+-type (as indicated by the label “P+SUB” in FIG. 5A). An epitaxial layer 553 is formed doped to an N-type (as indicated by the label “N EPI”). A well 557 is formed extending into the epitaxial layer 553 and is doped to a P-type (as indicated by the label “PWELL”). Metal contacts 408 are formed contacting the well 557 at the device side surface 560 for each of the TVS diodes 531, 533. The P+ substrate 551 forms an electrical connection for the diodes 531, 533 that are coupled together. Isolation trenches 561 extend through the well 557 (PWELL) and through the epitaxial layer 553 (N EPI) and into the P+ substrate 551 (P+SUB but not through it, and isolate the vertical diodes 531, 533 from one another while connecting them through the semiconductor substrate. A protective overcoat layer 569 is formed over the device side surface 560.

Stud bumps 565 are formed over and contacting the metal contacts 508 and form terminals for the semiconductor die 505. The stud bumps 565 form surface mount terminals for the semiconductor die 505.

FIG. 5B illustrates in another cross-sectional view the arrangement of FIG. 5A with current I_{ESD} shown flowing in a ESD discharge transient event. In contrast to the arrangement of FIG. 4B, the ESD current flows through the semiconductor substrate 551, and no backside metal is used. The arrangement of FIG. 5B relies on current flowing through the semiconductor substrate 551 to couple the two diodes 531, 533 together to form the TVS diode device (see TVS diode device 200 in FIG. 3, for example). As shown in FIG. 5B, the current I_{ESD} flows through the stud bumps and through the TVS diodes 531, 533 using the semiconductor substrate 551 to electrically couple the TVS diodes. For a negative transient event where ground “GND” is at a voltage higher than the potential at the IO signal, the current I_{ESD} flows in the opposite direction than that shown.

FIGS. 6A-6G illustrate, in a series of cross-sectional views, selected major steps used in an example WCSP process for forming the arrangements.

In FIG. 6A, a portion of a semiconductor wafer 601 is shown in cross-sectional view after example semiconductor dies 6051, 6052 are formed spaced from one another by a scribe lane 603. The semiconductor dies 6051, 6052 are replicated, and each semiconductor die 6051, 6052 has a TVS diode device formed on it with two diodes 631, 633 coupled to one another (see, for example, diodes 231, 233 in the circuit of FIG. 3). Metal contacts 608 are on the device side surface 660 of the semiconductor dies 6051, 6052.

In FIG. 6A, each of the example semiconductor dies 6051, 6052 has a vertical P-N-P structure 650 that includes a P+ type doped semiconductor substrate 651 (labeled “P+SUB”), an N-type doped epitaxial layer 653 (labeled “N EPI” formed over the P+ type doped semiconductor substrate 651, and a P-type doped well 657 (labeled “PWELL”) formed at the device side surface 660 and extending into the N-type epitaxial layer 653. The metal contacts 608 are formed in openings in the protective overcoat layer 669, a dielectric material deposited over the device side surface 660. The metal contacts 608 contact the P-type well 657 for both the TVS diodes 631, 633 for each semiconductor die 6051, and form anode contacts for the diodes, which are arranged to have the cathodes in P+ type semiconductor substrate 651. The two semiconductor dies 6051, 6052 are shown as an example, in a practical semiconductor wafer 601, hundreds, thousands and even hundreds of thousands of the semiconductor dies 6051, 6052 will be arranged in rows and columns and spaced apart by scribe lanes (see, for example, wafer 101 in FIG. 1A, with dies 105, and scribe lanes 103, 104).

FIG. 6B illustrates the semiconductor wafer 601 of FIG. 6A after additional processing. In FIG. 6B, stud bumps 665 are formed over the metal contacts 608 for each of the diodes 631, 633 of each of the dies (6051, 6052). In an example process, a wafer bumping process can be performed, where openings are formed in the protective overcoat layer 669, and plating processes form the stud bumps 665, which can be of copper, gold, or other metals or alloys, and additional plating (not shown) can be formed on the stud bumps to prevent tarnish or corrosion, such as nickel, gold, palladium, or silver.

FIG. 6C illustrates, in another cross-sectional view, the semiconductor wafer 601 of FIG. 6B after an additional process step. A support tape 671 is applied to the stud bumps 665 over the device side surface 660 of the semiconductor wafer 601. The support tape 671 is used to temporarily hold the semiconductor wafer 601 during backside processes that will be performed in subsequent steps. These steps are optional, for the arrangements shown in FIGS. 5A-5B, these backside processing steps are not performed, and can be skipped. For the arrangements where no backside metal is used, a wafer thickness of about 7.5 mils (about 190 microns) is used.

FIG. 6D illustrates the results of a wafer thinning step performed on the semiconductor wafer 601 of FIG. 6C, the wafer 601 is rotated so that the backside faces upwards and can be ground or polished. The wafer 601 can be thinned to a wafer thickness of approximately 4 mils (about 100 microns) by a mechanical grinding process.

FIG. 6E illustrates the semiconductor wafer 601 of FIG. 6D after an additional process. In FIG. 6E, a backside metal 659 is shown deposited on the backside of semiconductor wafer 601. The backside metal 659 also couples the diodes 631, 633 on each semiconductor die 6051, 6052 together. The backside metal 659 can be aluminum, copper, or another conductive metal or alloy, and may be deposited in a pressure vapor deposition (PVD) tool, for example.

FIG. 6F illustrates the semiconductor wafer 601 of FIG. 6E after an additional process. In FIG. 6F, a backside coating 675 is shown formed over the backside metal 659. The backside coating 675 can be epoxy resin mold compound, or another epoxy, resin or plastic, and is an insulating material that protects the backside metal 659.

FIG. 6G illustrates the semiconductor dies 6051, 6052 of FIG. 6F after a singulation step separates them one from another. In the singulation step, a mechanical saw or another dicing tool cuts through the semiconductor wafer 601 along the scribe lane 603 between the semiconductor dies. Each semiconductor die 6051, 6052 has a pair of back-to-back diodes 631, 633 which are arranged with stud bumps 665 forming terminals. As shown in FIG. 3, the diodes can be coupled between a signal and ground (see FIG. 3, diodes 231, 233) to provide a TVS diode device to protect a signal.

The semiconductor dies 6051, 6052 in FIG. 6G correspond to the arrangements shown in FIGS. 4A, 4B (semiconductor die 405 with diodes 431, 433) with the backside metal (459 in FIGS. 4A-4B. 659 in FIG. 6G) coupling the cathodes of the diodes together. The semiconductor dies 6051, 6052 in FIG. 6B can be singulated without use of the optional backside processing steps of FIGS. 6C-6F to form the arrangements shown in FIGS. 5A-5B, the dies 6051, 6052 in FIG. 6B corresponding the semiconductor die 505 in FIGS. 5A-5B, with no backside metal.

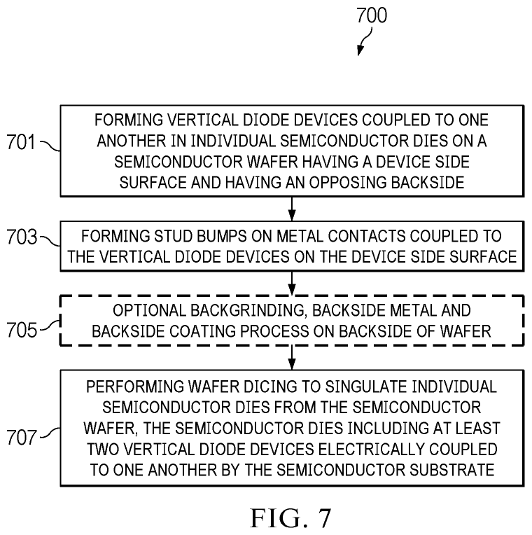

FIG. 7 illustrates, in a flow diagram 700, major steps of a method for forming the arrangements.

In FIG. 7, at step 701, a wafer fabrication process forms vertical diode devices coupled to one another in individual semiconductor dies on a semiconductor wafer having a device side surface and having an opposing backside. (See, for example, FIG. 6A, semiconductor dies 6051, 6052 in semiconductor wafer 601, with vertical diodes 631, 633).

At step 703, the method continues by forming stud bumps on metal contacts coupled to the vertical diode devices on the device side (see, for example, FIG. 6B, with stud bumps 665 formed on the metal contacts 608 of the semiconductor dies 6051, 6052).

At step 705, the method continues with backside processing steps that are optional. Optional backgrinding, backside metal deposition and backside coating processes on can be performed on the backside of the semiconductor wafer. (See, for example, the semiconductor wafer 601 in FIG. 6C where a temporary support 671 is applied over the stud bumps 665 for backside processing, the semiconductor wafer 601 in FIG. 6D after a wafer thinning backgrinding step, the semiconductor wafer 601 in FIG. 6E after a backside metal 659 is deposited on the semiconductor wafer 601, and the semiconductor wafer 601 in FIG. 6F, after a backside coating 661 is formed over the backside metal 659).

At step 707, the method shown in FIG. 7 completes by performing wafer dicing to singulate individual semiconductor dies from the semiconductor wafer, the semiconductor dies including at least two vertical diode devices coupled to one another by the semiconductor substrate. (See, for example, the semiconductor dies 6051, 6052, in FIG. 6G, after singulation to separate the dies one from another). To confirm operation of the TVS diode devices, a wafer probe test can be performed to identify working and failed devices prior to dicing the wafer, so that only functional devices are used and failed devices can be scrapped or subjected to additional analysis to correct issues in the process.

The example arrangements provide TVS diode devices with ultra-low capacitance and a small footprint (when compared to packaged TVS diode devices formed using a prior approach without the advantages of the arrangements), the devices are ready for SMT mounting to a system board or module. By use of the WCSP methods of the arrangements, the TVS diode devices are formed without the use of leadframes or other package substrates, die attach and die mounting, wire bonding, or molded packages, and are low in cost, while providing low capacitance and high performance (when compared to TVS diode devices formed without use of the arrangements).

Modifications are possible in the described arrangements, and other alternative arrangements are possible within the scope of the claims.

What is claimed is:

1. A method, comprising:
forming vertical diode devices coupled to one another in individual semiconductor dies on a semiconductor wafer having a device side surface and having an opposing backside surface;
forming stud bumps on metal contacts coupled to the vertical diode devices on the device side surface; and
performing wafer dicing to singulate the individual semiconductor dies from the semiconductor wafer, the individual semiconductor dies including at least two of the vertical diode devices electrically coupled to one another by a semiconductor substrate of the semiconductor wafer, the stud bumps forming terminals of the individual semiconductor dies.

2. The method of claim 1, and further comprising:
prior to performing the wafer dicing, forming a backside metal on the backside surface of the semiconductor wafer, the backside metal and the semiconductor substrate electrically coupling the at least two of the vertical diode devices together.

3. The method of claim 2, wherein forming the backside metal on the backside surface of the semiconductor wafer further comprises:
attaching a temporary support on the device side surface;
grinding the backside surface of the semiconductor wafer to reduce a thickness of the semiconductor wafer;
coating the backside surface of the semiconductor wafer with the backside metal; and
removing the temporary support.

4. The method of claim 3, and further comprising:
prior to removing the temporary support, forming a backside coating of epoxy resin mold compound, epoxy, resin or plastic over the backside metal.

5. The method of claim 1, wherein forming vertical diode devices further comprises:
forming a diffusion region of a P-type or an N-type conductivity in the device side surface of a first epitaxial layer of a conductivity type that is opposite the conductivity type of the diffusion region, wherein the first epitaxial layer is formed over a semiconductor substrate of a P-type or N-type conductivity that has the same conductivity type as the diffusion region, wherein the vertical diodes have a vertical P-N-P structure or a vertical N-P-N structure from the diffusion region, through the first epitaxial layer, and to the semiconductor substrate.

6. The method of claim 5, and further comprising forming isolation trenches of insulating material that extend from the device side surface through the diffusion region, through the first epitaxial layer and into, but not through, the semiconductor substrate between the vertical diode devices.

7. The method of claim 5, wherein the diffusion region is a P-type diffusion region, the first epitaxial layer is an N-type epitaxial layer, and the semiconductor substrate is a P+ type semiconductor substrate.

8. The method of claim 5, wherein the diffusion region is an N-type diffusion region, the first epitaxial layer is a P-type epitaxial layer, and the semiconductor substrate is an N+ type semiconductor substrate.

9. The method of claim 5, where forming the vertical diode devices further comprises forming Zener diodes at a P-N junction between the first epitaxial layer and the semiconductor substrate.

10. The method of claim 9, wherein forming the stud bumps further comprises forming stud bumps that are coupled to cathodes of the Zener diodes.

11. The method of claim 9, wherein forming the stud bumps further comprises forming stud bumps that are coupled to anodes of the Zener diodes.

12. The method of claim 9, wherein forming the vertical diode devices further comprises forming a first vertical diode and a second vertical diode in the individual semiconductor dies, the first vertical diode coupled to a first one of the terminals, the second vertical diode coupled to a second one of the terminals different from the first one of the terminals.

13. The method of claim 12, wherein the individual semiconductor dies are free from a backside metal coating.

14. The method of claim 13, wherein prior to performing the wafer dicing, no backside thinning is performed.

15. A packaged semiconductor device, comprising:
at least two vertical diode devices in a semiconductor die, the at least two vertical diode devices spaced from one another by isolation trenches, each comprising:
a first diffusion region of a first P-type or N-type conductivity formed in a device side surface of a semiconductor die, the first diffusion region extending into a first epitaxial layer of a second P-type or N-type conductivity opposite the first conductivity type;
the first epitaxial layer formed over a semiconductor substrate of the semiconductor device and having the first P-type or N-type conductivity, the semiconductor substrate having a backside surface facing away from the device side surface of the semiconductor die;
metal contacts on the device side surface of the semiconductor die electrically coupled to the first diffusion regions; and
stud bumps formed on the metal contacts and arranged to form terminals of the packaged semiconductor device.

16. The packaged semiconductor device of claim 15, and further comprising:
a layer of backside metal covering the backside surface of the semiconductor die, the backside metal and the semiconductor substrate electrically coupling the at least two vertical diode devices.

17. The packaged semiconductor device of claim 16, and further comprising a backside coating of dielectric material over the layer of backside metal on the semiconductor die.

18. The packaged semiconductor device of claim 15, wherein the first diffusion region is a P-type diffusion region, the first epitaxial layer is an N-type epitaxial layer, and the semiconductor substrate is a P+ type substrate, the at least two vertical device diodes having a P-N-P structure from the first diffusion region to the first epitaxial layer and to the semiconductor substrate.

19. The packaged semiconductor device of claim 15, wherein the first diffusion region is an N-type diffusion region, the first epitaxial layer is a P-type epitaxial layer, and the semiconductor substrate is an N+ type substrate, the at least two vertical device diodes having an N-P-N structure from the first diffusion layer to the first epitaxial layer and to the semiconductor substrate.

20. The packaged semiconductor device of claim 15, wherein the at least two vertical diode devices comprise a Zener diode formed at a P-N junction between the first epitaxial layer and the semiconductor substrate.

21. The packaged semiconductor device of claim 20, wherein the Zener diodes of the at least two vertical diode devices are electrically coupled by the semiconductor substrate.

22. The packaged semiconductor device of claim 15, and further comprising:
a second epitaxial layer of the first P-type or N-type conductivity over the semiconductor substrate and between the semiconductor substrate and the first epitaxial layer; and
a buried layer of a P-type or N-type conductivity over the second epitaxial layer and covered by the first epitaxial layer.

23. The packaged semiconductor device of claim 22, wherein:
the at least two vertical diode devices further comprise a second diffusion region of the N-type or P-type conductivity opposite the conductivity type of the first diffusion region and extending into the first epitaxial layer at the device side surface of the first epitaxial layer, the second diffusion region isolated from the first diffusion region by isolation trenches and having a metal contact coupled to the stud bump that is coupled to the first diffusion region.

24. The packaged semiconductor device of claim 15, wherein the at least two diode devices comprise at least one first diode device and at least one second diode device, and the stud bumps comprise a first stud bump coupled to the at least one first diode device and a second stud bump coupled to the at least one second diode device.

25. The packaged semiconductor device of claim 24, wherein the first stud bump and the second stud bump are configured to be coupled between a signal and a ground, so that the at least one first diode device and the at least one second diode device form a transient voltage suppression (TVS) diode device for the signal.

26. A transient voltage suppression (TVS) diode device, comprising:
a pair of vertical diode devices coupled together, each vertical diode device comprising:
a P-type diffusion well formed at the device side surface of a semiconductor die, the well extending into an N-type epitaxial layer;
a P+ type semiconductor substrate, the N-type epitaxial layer formed over a device side surface of the P+ type semiconductor substrate;
isolation trenches extending from the device side surface of the semiconductor die through the P-type diffusion wells, through the N-epitaxial layer, and into but not through the P+ semiconductor substrate, wherein the isolation trenches separate the pair of diode devices one from another;
metal contacts formed on and electrically contacting the device side surface of the P-type diffusion wells; and
stud bumps formed on the metal contacts to form terminals coupled to the diode devices.

27. The transient voltage suppression (TVS) diode device of claim 26, and further comprising:
a backside metal layer formed on a backside surface of the semiconductor die facing away from the device side surface, the backside metal layer and the P+ type semiconductor substrate electrically coupling the pair of vertical diode devices together.

28. The transient voltage suppression (TVS) diode device of claim 27, and further comprising:
a backside coating of a dielectric material formed over the backside metal layer.

29. The transient voltage suppression (TVS) diode device of claim 26, wherein each vertical diode device comprises a Zener diode formed at a P-N junction between the P+ type semiconductor substrate and the N-type epitaxial layer.

30. The transient voltage suppression (TVS) diode device of claim 26,
wherein the pair of vertical diode devices are configured to provide transient voltage suppression (TVS) to a signal when one of the terminals is coupled to the signal and the other one of the terminals is coupled to ground.
